(19) United States
(12) Patent Application Publication
(10) Pub. No.: US 2025/0329593 A1
(43) Pub. Date: Oct. 23, 2025

(54) PACKAGE STRUCTURES OF SEMICONDUCTOR DEVICES

(71) Applicant: Yangtze Memory Technologies Co., Ltd., Wuhan (CN)

(72) Inventors: Li TAO, Wuhan (CN); Baohua ZHANG, Wuhan (CN); Shanshan ZHAO, Wuhan (CN)

(21) Appl. No.: 18/789,945

(22) Filed: Jul. 31, 2024

Related U.S. Application Data
(63) Continuation of application No. PCT/CN2024/088500, filed on Apr. 18, 2024.

(51) Int. Cl. H01L 23/31; H01L 23/29; H01L 23/495; H01L 23/498; H01L 25/065

(52) U.S. Cl. CPC H01L 23/3114; H01L 23/293; H01L 23/49568; H01L 23/49816; H01L 25/0657

(57) ABSTRACT

Package structures and methods for manufacturing package structures are described. An example package structure includes a substrate, a chip disposed on a first surface of the substrate, corner structures disposed on corner areas of the first surface, and an encapsulation structure encapsulating the chip, where the encapsulation structure covers a surface of the chip and a first area of the first surface of the substrate that extends beyond the chip. The substrate includes a first material, and the corner structures include a second material. The first material is the same as the second material, or the first material is similar to the second material in that a difference in at least one of electrical insulation resistivity or thermal expansion coefficient between the first material and the second material is below a threshold.

### CROSS-REFERENCE TO RELATED APPLICATIONS

This application is a continuation of International Application No. PCT/CN2024/088500, filed on Apr. 18, 2024, the disclosure of which is hereby incorporated by reference in its entirety.

### TECHNICAL FIELD

The present disclosure generally relates to package structures, and more specifically, to package structures of semiconductor devices.

### BACKGROUND

The package structure for chips, often referred to in the context of integrated circuits (ICs) or semiconductor devices, is crucial for protecting the chips, facilitating electrical connections, and dissipating heat. The structure of a chip package can vary widely depending on the application, performance requirements, and the specific technology used.

### SUMMARY

The present disclosure describes package structures of semiconductor devices.

In one aspect, the present disclosure describes a package structure. The package structure includes a substrate, a chip disposed on a first surface of the substrate, corner structures disposed on corner areas of the first surface, and an encapsulation structure encapsulating the chip, where the encapsulation structure covers a surface of the chip and a first area of the first surface of the substrate that extends beyond the chip. The substrate includes a first material, and the corner structures include a second material. The first material is the same as the second material, or the first material is similar to the second material in that a difference in at least one of electrical insulation resistivity or thermal expansion coefficient between the first material and the second material is below a threshold.

In another aspect, the present disclosure describes a package structure. The package structure includes a substrate, a chip disposed on a first surface of the substrate, corner structures disposed on corner areas of the first surface, and encapsulation structure encapsulating the chip, where the encapsulation structure covers a surface of the chip and a first area of the first surface of the substrate that extends beyond the chip. The substrate includes first contact structures and first solder bumps coupled to the first contact structures, and the first solder bumps are placed on a second surface of the substrate opposing the first surface of the substrate. At least one of the corner structures includes second contact structures and second solder bumps coupled to the second contact structures, and the second solder bumps are placed on an outward surface of the at least one of the corner structures that is opposing the second surface of the substrate.

In still another aspect, the present disclosure describes a package structure. The package structure includes a substrate, chips stacked on a first surface of the substrate, corner structures disposed on corner areas of the first surface of the substrate, and an encapsulation structure encapsulating the chips, where the encapsulation structure covers a surface of at least one of the chips and a first area of the first surface of the substrate. The substrate includes a first material, and the corner structures include a second material. The first material is the same as the second material, or the first material is similar to the second material in that a difference in at least one of electrical insulation resistivity or thermal expansion coefficient between the first material and the second material is below a threshold.

The details of one or more implementations of the subject matter of this disclosure are set forth in the accompanying drawings and the description below. Other features, aspects, and advantages of the subject matter will become apparent from the description, the drawings, and the claims.

### BRIEF DESCRIPTION OF THE DRAWINGS

FIG. 1 illustrates an example of a package structure, in accordance with one or more implementations of the present disclosure.

FIG. 2 illustrates an example of a package structure, in accordance with one or more implementations of the present disclosure.

FIG. 3 illustrates an example of a package structure, in accordance with one or more implementations of the present disclosure.

FIG. 4 illustrates an example of a package structure, in accordance with one or more implementations of the present disclosure.

FIG. 5 illustrates an example of a supporting structure, in accordance with one or more implementations of the present disclosure.

FIG. 6 illustrates an example of a package structure, in accordance with one or more implementations of the present disclosure.

FIG. 7 illustrates an example of a package structure, in accordance with one or more implementations of the present disclosure.

FIG. 8 illustrates an example of a package structure, in accordance with one or more implementations of the present disclosure.

FIG. 9 illustrates an example of a package structure, in accordance with one or more implementations of the present disclosure.

FIG. 10 illustrates a block diagram of an example process of manufacturing a package structure, in accordance with one or more implementations of the present disclosure.

FIGS. 11A-11D illustrate an example process of manufacturing a package structure, in accordance with one or more implementations of the present disclosure.

Like reference numbers and designations in the various drawings indicate like elements.

### DETAILED DESCRIPTION

The semiconductor package is an integral component in the electronics industry, serving as the protective housing for semiconductor devices or integrated circuits (ICs). This packaging not only safeguards the delicate silicon die against environmental and mechanical stresses but also plays an important role in heat dissipation, electrical performance, and reliable connectivity to external circuits.

In some implementations, a semiconductor package structure includes several elements. At the core lies the semiconductor die, which is the actual silicon chip containing the microscopic electronic circuits fabricated using semiconductor manufacturing processes. The die is affixed to a substrate or a lead frame within the package, which provides structural support and a pathway for electrical connections.

In some implementations, electrical connectivity between the die and the package is achieved through bonding wires or, in more advanced packages, through direct bump connections in a flip-chip configuration. The bonding wires, which can be made from gold or aluminum, create fine electrical connections from the die to the lead frame or substrate pads. In flip-chip technology, solder bumps or copper pillars are used to directly connect the die to the substrate, reducing the package's size and improving electrical performance.

In some implementations, an assembly of integrated circuit is encapsulated within a protective material, such as an epoxy resin or a plastic compound, forming the external body of the package. This encapsulation shields the internal components from physical damage, moisture, and chemical contaminants, ensuring the device's longevity and reliability.

For thermal management, especially in high-performance devices, the package design may include heat sinks, heat spreaders, or thermal vias that facilitate heat dissipation away from the die. Efficient thermal management can help maintain operational integrity and prevent premature failure of the semiconductor device.

The external connections of the package, which interface with the circuit board or other components, can take various forms, including pin arrays for through-hole mounting or solder balls for surface mounting in ball grid array (BGA) configurations. The choice of external connection type is influenced by factors such as the application's space constraints, electrical requirements, and manufacturing considerations.

Semiconductor packages come in a myriad of configurations, tailored to specific application needs, ranging from simple dual in-line packages (DIPs) to complex multi-chip modules (MCMs) and system-on-chip (SoC) solutions. The ongoing evolution of semiconductor package technology continues to address the demands for higher performance, increased functionality, and greater miniaturization in the electronics industry.

In semiconductor device fabrication, a commonly encountered issue pertains to the phenomenon of warpage observed in the corners of semiconductor substrates, alongside the encapsulation layers enveloping these substrates. The warpage, characterized by an undesired deviation from the intended planar configuration, emerges due to disparities in thermal expansion coefficients amongst the constituent materials of the semiconductor package. Such materials include, but are not limited to, materials of the substrate, the die affixed to the substrate, and the encapsulation medium, each responding differently to temperature variations.

The encapsulation process, involving the application of materials such as epoxy or polymers that solidify post-application, further exacerbates this issue. For example, the encapsulant's curing and subsequent cooling introduce uneven contraction forces, contributing to the warpage. The design intricacies and the physical thinness of these layers amplify their susceptibility to bending, thereby increasing the likelihood of warpage due to asymmetric stress distributions.

The ramifications of warpage extend to degradation of the semiconductor device's reliability and performance. Notably, it jeopardizes the integrity of electrical connections, such as those in BGA packages, potentially leading to discontinuities or compromised connections. Furthermore, the structural integrity of the package might be undermined, manifesting in the form of cracks or delamination of package components. From a thermal management perspective, warpage can impede effective heat dissipation, thereby elevating device temperatures and diminishing operational efficiency.

Furthermore, mechanical impacts, particularly on the edges and corners of the package, pose a risk to the integrity and functionality of the encapsulated chip. These peripheral areas can be inherently more vulnerable to external forces due to their exposed positioning and the concentration of mechanical stresses they endure during impact. Such impacts can lead to a variety of detrimental effects on the chip, including, but not limited to, crack initiation and propagation, delamination of package layers, and disruption of internal connections. The susceptibility of these critical areas to mechanical damage not only compromises the reliability of the semiconductor device but also its operational lifespan. Consequently, addressing this vulnerability through innovative package design and protective measures is paramount in enhancing the durability and performance of semiconductor devices in real-world applications.

Moreover, in semiconductor packages where interconnect interfaces are exclusively positioned at the back side, diagnosing failures presents a challenge. The inherent design necessitates the disassembly of the package to access these interfaces for thorough analysis and identification of faults. However, this disassembly process is fraught with risks, particularly the potential for inflicting further damage to the semiconductor device. Such damage not only complicates the diagnostic process but may also render the device potentially inoperable, thereby exacerbating the issue. This underscores the need for innovative packaging solutions that facilitate easier access to interconnect interfaces for efficient problem resolution, while reducing the risk of damage during the diagnostic process.

To address these challenges, example techniques are described herein for mitigating warpage and improving mechanical strength of corners and edges. In some implementations, the described techniques can include a multifaceted design of package structures. For example, in some examples as described below in the disclosure, the encapsulant material at the edges and corners of the package structures can be designed to use the same material as the substrate, potentially improving the deformation caused by the mismatch in thermal expansion between the encapsulant and the substrate, and mitigating or preventing warping of the package edges and corners. The edges and corners of the package structures, which include the same material as the substrate, can be used to provide more contact structures to lead out internal interconnect pads, increasing the interconnect density of the package. Therefore, this design not only mitigates warping in the package structures, but also increases the available area for interconnections. In some examples, the corner and/or edge portions can be designed to incorporate contact structures with materials of high thermal conductivity to enhance the package's capability for heat dissipation. By leveraging the thermal conductive properties of these materials within the contact structures, it can facilitate the removal of excess heat, thereby contributing to the improved thermal management and overall performance stability of the device.

In some examples, high-strength supporting structures, such as clamps or braces, are placed at the corners and/or edges of the packages to strengthen the corners and edges. The high strength supporting structures can enhance the structural integrity of the package's edges and corners, serving as a safeguard against mechanical impacts that the package may encounter. This reinforcement can ensure the protection of the internal chip, mitigating the risk of damage from external forces and preserving the operational reliability of the encapsulated semiconductor device.

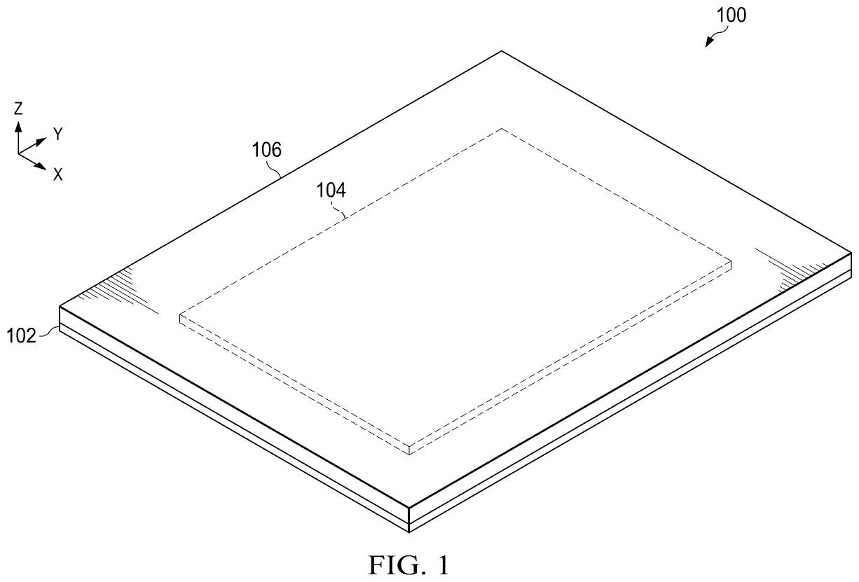

FIG. 1 illustrates an example of a package structure 100, according to one or more implementations of the disclosure. As shown, package structure 100 includes substrate 102, chip 104 disposed on substrate 102, and encapsulation structure 104 encapsulating chip 104.

In some cases, substrate 102 can be composed of a rigid or flexible material that provides mechanical support for the mounted semiconductor devices, such as chip 104, and facilitates the electrical interconnection between these devices and external circuitry. In some examples, substrate 102 can include any suitable material including, but not limited to, ceramic, silicon, or organic materials like Bismaleimide-Triazine (BT) resin, FR4 (a fiberglass-reinforced epoxy laminate), and polyimide.

In some examples, substrate 102 incorporates multiple layers, including conductive traces and vias, which enable the routing of electrical signals, power, and ground connections throughout the package. Additionally, the substrate 102 can include specialized areas or pads for the attachment of semiconductor dies, as well as for the placement of external connection points such as solder balls or pins in BGA or Pin Grid Array (PGA) configurations, respectively.

Substrate 102 can also integrate passive components, such as resistors or capacitors, and employ materials with specific thermal, electrical, or mechanical properties to address particular performance requirements. For example, substrate 102 can use high thermal conductivity materials in areas prone to high heat generation, to aid in heat dissipation and maintain the reliability and longevity of the semiconductor devices.

Substrate 102's design can be tailored to accommodate various package types and configurations, ranging from simple single-chip packages to complex multi-chip modules (MCMs), ensuring versatility across a wide range of applications.

The dimensions of substrate 102, including its thickness and overall size, can be tailored to the specific requirements of the package. Thickness of substrate 102 can vary from thin layers in the range of a few hundred micrometers for flexible substrates to more substantial dimensions for rigid substrates, depending on the mechanical stability and thermal management needs of the device. Substrate 102's size can be related to the number and size of the devices it is designed to support, as well as the complexity of the circuitry it accommodates.

Within the structure of package structure 100, chip 104 includes functional electronic circuitry composed of micro-scale electronic elements, including but not limited to transistors, diodes, and passive components, which are interconnected to execute a diverse spectrum of electronic functions ranging from data processing to signal amplification.

Chip 104 can be any suitable type of chip, including but not limited to microprocessor chips, memory chips, microcontroller chips, digital signal processor (DSP) chips, field-programmable gate array (FPGA) chips, application-specific integrated circuit (ASIC) chips, or graphics processing unit (GPA) chips.

Chip 104 can be fabricated from semiconductor materials, such as silicon (Si), gallium arsenide (GaAs), silicon carbide (SiC), gallium nitride (GaN), germanium (Ge), or silicon germanium (SiGe).

The dimensions of chip 104 can be measured, for example, in millimeters or micrometers, contingent upon the complexity and intended application of the circuitry. The patterning and layering of circuit elements on chip 104 can be achieved through manufacturing techniques such as lithography and chemical deposition, ensuring the realization of highly compact and efficient designs.

As shown, chip 104 is encapsulated within encapsulation structure 106. Encapsulation structure 106 can provide chip 104 with protection against environmental hazards such as moisture, contaminants, and physical impacts. The material of encapsulation structure 106 can be selected to ensure compatibility with chip 104 and other package components, focusing on properties such as thermal stability, mechanical strength, and chemical resistance. In some examples, encapsulation structure 106 can be composed of any suitable material, including but not limited to epoxy resins, silicone, polyurethanes, acrylics, thermoplastics, or ceramics.

Encapsulation structure 106 can be fabricated by dispensing or molding an encapsulant material around chip 104, for example, under controlled conditions to prevent the introduction of voids and ensure uniform coverage. Once cured, the encapsulant material forms a solid protective layer that effectively shields chip 104, while also contributing to the overall structural integrity of package structure 100.

Encapsulation structure 106 can also facilitate the thermal management of package structure 100, aiding in the dissipation of heat generated by chip 104 during operation. The electrical insulating properties of encapsulation structure 106 can assist in preventing short circuits and maintaining the electrical performance of package structure 100.

Package structure 100 integrates substrate 102, chip 104, and encapsulation structure 106 to protect and enable the device's function. Chip 104, embedded with electronic circuits, is mounted on substrate 102, which provides structural support and electrical connections. Encapsulation structure 106 shields chip 104 from environmental damage while aiding in thermal management and mechanical stability. This cohesive assembly ensures the device's performance and reliability.

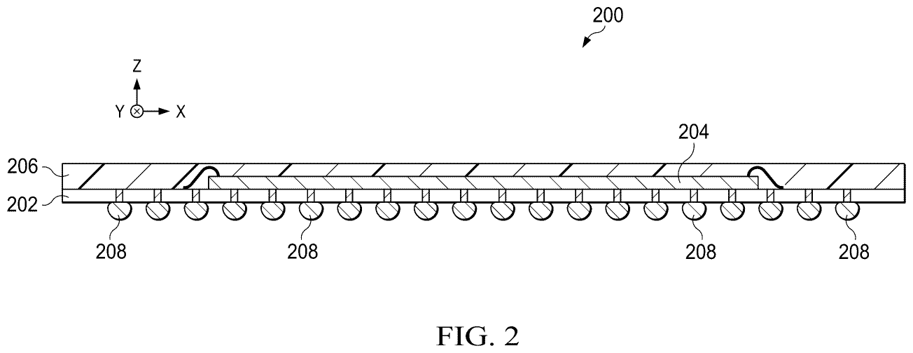

FIG. 2 illustrates an example side view of a package structure 200, according to one or more implementations of the disclosure. As shown, package structure 200 includes substrate 202, chip 204 disposed on a front side of substrate 202, encapsulation structure 206 encapsulating chip 204, and solder bumps 208 disposed on a back side of substrate 202, where the back side is opposite to the front side of substrate 202. In some implementations, package structure 200 is an example side view of package structure 100 in FIG. 1. For the sake of brevity, the description of the elements in FIG. 2 that are substantially the same or similar to those previously described in FIG. 1 will not be reiterated here. It is to be understood that these elements possess analogous structural and functional characteristics as those discussed with reference to FIG. 1.

Substrate 202 can be composed of a rigid or flexible material that provides mechanical support for the mounted semiconductor devices, such as chip 204, and facilitates the electrical interconnection between these devices and external circuitry. Substrate 202 can include any suitable material, including but not limited to ceramic, silicon, or organic materials like BT resin, FR4, and polyimide.

In the shown example, solder bumps 208 are disposed on a back side of substrate 202. Solder bumps 208 serve as the means of electrical and mechanical connection between substrate 202 and other components/systems, such as a printed circuit board (PCB). In some examples, solder bumps 208 have spherical or near-spherical formations that are arrayed on a surface of substrate 208, facilitating the establishment of interconnections. The dimensions of solder bumps 208 can be determined based on the specific requirements of package structure 200, with diameters ranging from a few micrometers to several hundred micrometers.

In some implementations, the arrangement of solder bumps 208 can follow a pre-defined pattern that aligns with corresponding contact structures in substrate 202, improving the efficiency of electrical pathways and reducing signal latency. This pattern can be designed in a grid-like configuration, such as BGA, which allows for a high density of connections within a limited space, enhancing the overall performance and scalability of the semiconductor device.

While the term “bump” suggests a rounded profile, the actual form post-reflow, a process where the solder is melted to create the bond, can vary from slightly flattened spheres to more complex shapes dictated by the reflow characteristics of the solder material and the surface tension interactions between the solder, pad, and any underfill material used. In some implementations, the solder bumps 208 can have different shapes. In some implementations, solder bumps can be referred to as solder points.

In some implementations, the material composition of solder bumps 208 can include lead-based or lead-free alloys, with the specific alloy chosen based on considerations such as melting temperature, mechanical strength, and compatibility with the thermal expansion properties of substrate 202 to ensure reliable electrical connections and mechanical stability throughout the device's operational lifespan.

Chip 204 includes functional electronic circuitry composed of micro-scale electronic elements including but not limited to transistors, diodes, and passive components, which are interconnected to execute a diverse spectrum of electronic functions ranging from data processing to signal amplification. Chip 204 can be any suitable type of chip, including but not limited to microprocessor chips, memory chips, microcontroller chips, DSP chips, FPGA chips, ASIC chips, or GPA chips. Chip 204 can be fabricated from semiconductor materials, such as silicon (Si), gallium arsenide (GaAs), silicon carbide (SiC), gallium nitride (GaN), germanium (Ge), or silicon germanium (SiGe).

Encapsulation structure 206 provides chip 204 with protection against environmental hazards such as moisture, contaminants, and physical impacts. The material of encapsulation structure 206 can be selected to ensure compatibility with chip 204 and other package components, for example, based on properties such as thermal stability, mechanical strength, and chemical resistance. In some examples, encapsulation structure 206 can be composed of any suitable material including, but not limited to, epoxy resins, silicone, polyurethanes, acrylics, thermoplastics, or ceramics.

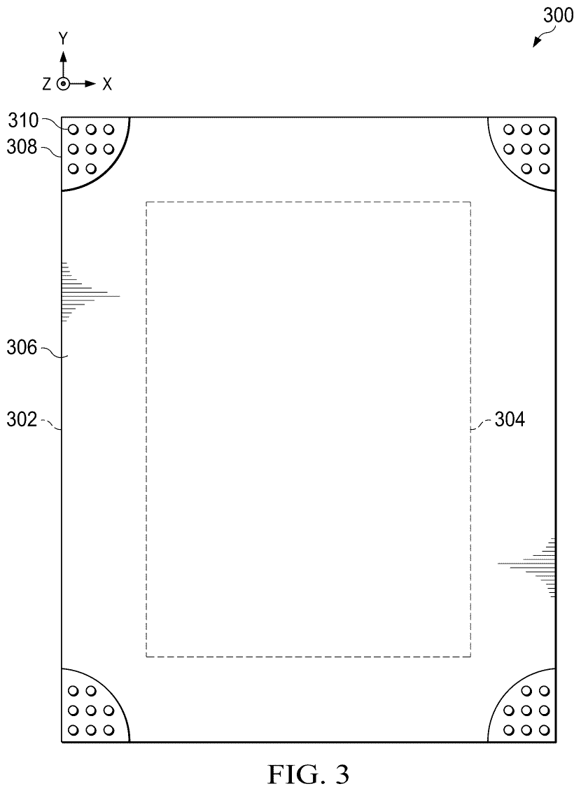

FIG. 3 illustrates an example top view of an example package structure 300, according to one or more implementations of the disclosure. As shown, package structure 300 includes substrate 302, chip 304 disposed on substrate 302, encapsulation structure 306 encapsulating chip 304, and corner structures 308 disposed on corner areas of substrate 302.

Substrate 302 can be composed of a rigid or flexible material that provides mechanical support for the mounted semiconductor devices, such as chip 304, and facilitates the electrical interconnection between these devices and external circuitry. Substrate 302 can include any suitable material including, but not limited to, ceramic, silicon, or organic materials like BT resin, FR4, and polyimide.

In some examples, substrate 302 incorporates multiple layers, including conductive traces and vias, which enable the routing of electrical signals, power, and ground connections throughout the package. Additionally, the substrate 302 can include specialized areas or pads for the attachment of semiconductor dies, as well as for the placement of external connection points such as solder balls or pins in BGA or PGA configurations, respectively.

Substrate 302 can also integrate passive components, such as resistors or capacitors, and employ materials with specific thermal, electrical, or mechanical properties to address particular performance requirements. For example, substrate 302 can use high thermal conductivity materials in areas prone to high heat generation, to aid in heat dissipation and maintain the reliability and longevity of the semiconductor devices.

Chip 304 is disposed on substrate 302. Chip 304 includes functional electronic circuitry composed of micro-scale electronic elements, including but not limited to transistors, diodes, and passive components, which are interconnected to execute a diverse spectrum of electronic functions ranging from data processing to signal amplification.

Chip 304 can be any suitable type of chip, including but not limited to microprocessor chips, memory chips, microcontroller chips, DSP chips, FPGA chips, ASIC chips, or GPA chips.

Chip 304 can be fabricated from semiconductor materials, such as silicon (Si), gallium arsenide (GaAs), silicon carbide (SiC), gallium nitride (GaN), germanium (Ge), or silicon germanium (SiGe).

Chip 304 is encapsulated within encapsulation structure 306. Encapsulation structure 306 covers a surface of chip 304 and a portion of a surface area of substrate 302 that extends beyond chip 304. Encapsulation structure 306 provides chip 304 with protection against environmental hazards such as moisture, contaminants, and physical impacts. The material of encapsulation structure 306 can be selected to ensure compatibility with chip 304 and other package components, focusing on properties such as thermal stability, mechanical strength, and chemical resistance. In some examples, encapsulation structure 306 can be composed of any suitable material, including but not limited to epoxy resins, silicone, polyurethanes, acrylics, thermoplastics, or ceramics.

Note that in the example of FIG. 3, package structure 300 is shown to include one chip for illustrative purposes. In some examples, package structure 300 can have any suitable number of chips, such as 2, 5, or 10. In some implementations, the chips can be stacked on substrate 302. In some implementations, the chips can be stacked in any suitable manner, such as in an overlapping manner or in a staircase manner.

In the shown example, corner structures 308 are disposed on corner areas of substrate 302, and encapsulation structure 306 does not extend to cover corner structures 308. In some implementations, encapsulation structure 306 covers a surface of chip 304 and a first area of a first surface (e.g., front surface) of substrate 302 that extends beyond chip 304. In some examples, the first area includes a portion of the first surface of substrate 302 that extends beyond chip 304, excluding the corner areas of the first surface.

In some implementations, substrate 302 includes a first material, and corner structures 308 include a second material. In some examples, the first material of substrate 302 is the same as the second material of corner structures 308. In some examples, the first material of substrate 302 is similar to the second material corner structures 308 in term of at least one of electrical insulation resistivity or thermal expansion coefficient. For example, a difference in at least one of electrical insulation resistivity or thermal expansion coefficient between the first material and the second material is within a range or below a threshold, such as 0.5-5% of the corresponding value of the first material or the second material.

One notable difference between package structure 300 in FIG. 3 and package structure 100 in FIG. 1 is that the corner portions of encapsulation structure 106 can be replaced by a material that is the same as or similar to, the material of substrate 102 to form the encapsulation structure 306 in package structure 300.

By using the same or similar material as substrate 302 for the encapsulant material at the corners of package structure 300, the warping of the package corners can be mitigated, potentially improving the deformation caused by the mismatch in thermal expansion between the encapsulation structure 306 and substrate 302.

Corner structures 308 are shaped and dimensioned with the exemplary implementations showcasing pie-shaped configurations. However, corner structures 308 are not limited to these configurations alone. In some examples, corner structures 308 can have any suitable geometries, including but not limited to square, rectangular, regular, or irregular shapes.

The size and geometry of each one of corner structures 308 can be determined based on several factors, including but not limited to the overall dimensions of substrate 302, the spatial requirements of the mounted components, and the intended application of the semiconductor package structure 300. In some examples, corner structures 308 can occupy approximately 10% of a portion of a surface area of substrate 302 that extends beyond chip 304 (or surface area of substrate 302 that is not covered by chip 304).

It should be noted that specific shapes and sizes are described throughout this disclosure as examples, and they are not meant to be limiting, and variations in the dimensions and geometries of the corner portions are anticipated to adapt to different package designs and functional requirements.

In some examples, corner structures 308 include contact structures (not shown) within corner structures 308 and solder bumps 310 that are coupled to the contact structures and that are disposed on an outward surface of corner structures 308 that is opposing a back surface of substrate 302. Solder bumps 310 serve as the means of electrical and mechanical connection between corner structures 308 and other components/systems. Corner structures 308, which include the same or substantially the same material as substrate 302, can be used to provide more solder bumps and contact structures to lead out internal interconnect pads, increasing the interconnect density of package structure 300. By utilizing the space provided by corner structures 308, more interconnect ports, such as solder bumps 310 and the contact structures coupled therewith, can be brought out on the upper surface of package structure 300, which can serve as testing and maintenance interfaces (to avoid package damage caused by desoldering at the back side) or connect with other package interconnect ports, increasing the overall interconnect density of the package structure 300.

In some examples, solder bumps 310 have spherical or near-spherical formations that are arrayed on a surface of corner structures 308, facilitating the establishment of interconnections. The dimensions of solder bumps 310 can be determined based on the specific requirements of corner structures 308, with diameters ranging from a few micrometers to several hundred micrometers.

The arrangement of solder bumps 310 can follow a pre-defined pattern that aligns with corresponding contact structures in corner structures 308, improving the efficiency of electrical pathways and reducing signal latency. This pattern can be designed in a grid-like configuration, such as BGA, which allows for a high density of connections within a limited space, enhancing the overall performance and scalability of the semiconductor device.

The material composition of solder bumps 310 can include lead-based or lead-free alloys, with the specific alloy chosen based on considerations such as melting temperature, mechanical strength, and compatibility with the thermal expansion properties of corner structures 308 to ensure reliable electrical connections and mechanical stability throughout the device's operational lifespan.

Corner structures 308 incorporating solder bumps 310 and contact structures therewith can serve various purposes, such as facilitating alignment during assembly, enabling enhanced interconnectivity with adjoining modules, or providing designated areas for additional functional elements like testing points or thermal management features.

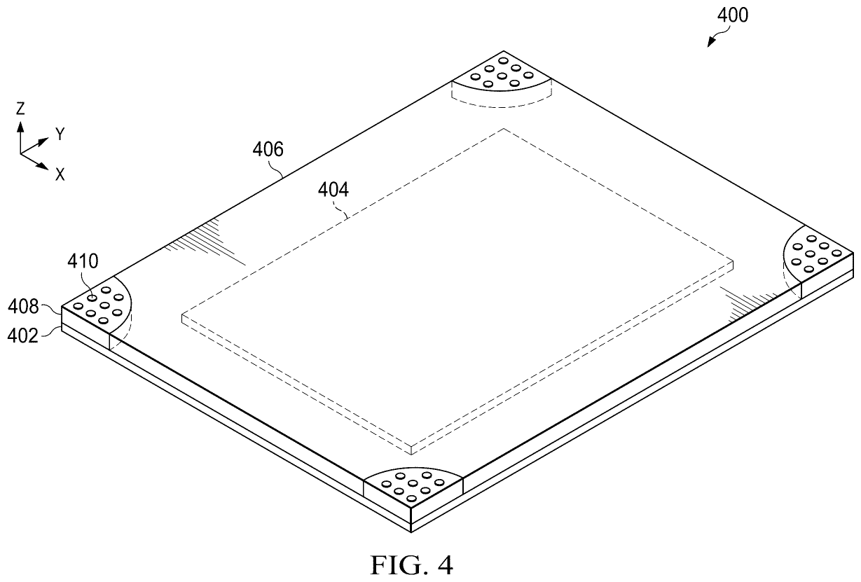

FIG. 4 illustrates an example perspective view of an example package structure 400, according to one or more implementations of the disclosure. As shown, package structure 400 includes substrate 402, chip 404 disposed on substrate 402, encapsulation structure 406 encapsulating chip 404, and corner structures 408 disposed on corner areas of substrate 402. In some implementations, package structure 400 is an example, at a perspective view, of package structure 300 in FIG. 3. For the sake of brevity, the description of the elements in FIG. 4 that are substantially the same or similar to those previously described in FIG. 3 will not be reiterated here. It is to be understood that these elements possess analogous structural and functional characteristics as those discussed with reference to FIG. 3.

In the shown example, corner structures 408 are disposed on corner areas of a surface of substrate 402, and encapsulation structure 406 does not extend to cover corner structures 408. In some implementations, substrate 402 includes a first material, and corner structures 408 include a second material. In some examples, the first material of substrate 402 is the same as the second material of corner structures 308. In some examples, the first material of substrate 402 is similar to the second material corner structures 408 in terms of at least one of electrical insulation resistivity or thermal expansion coefficient. For example, a difference in at least one of electrical insulation resistivity or thermal expansion coefficient between the first material and the second material is within a range or below a threshold, such as 0.5%-5% of the corresponding value of the first material or the second material.

By using the same or similar material as substrate 402 for the encapsulant material at the corners of package structure 400, the warping of package corners can be mitigated, potentially improving the deformation caused by the mismatch in thermal expansion between the encapsulation structure 406 and substrate 402.

Corner structures 408 are shaped and dimensioned with the exemplary implementations showcasing pie-shaped configurations. However, corner structures 408 are not limited to these configurations alone. In some examples, corner structures 408 can have any suitable geometries, including but not limited to square, rectangular, regular, or irregular shapes.

The size and geometry of each one of corner structures 408 can be determined based on several factors, including but not limited to the overall dimensions of substrate 402, the spatial requirements of the mounted components, and the intended application of the semiconductor package structure 400. In some examples, corner structures 408 can occupy approximately 10% of a portion of a surface area of substrate 402 that extends beyond chip 404 (or surface area of substrate 402 that is not covered by chip 404).

In some examples, corner structures 408 include contact structures (not shown) within corner structures 408 and solder bumps 410 coupled to the contact structures. Corner structures 408, which include the same or substantially the same material as substrate 402, can be used to provide more solder bumps and contact structures to lead out internal interconnect pads, increasing the interconnect density of package structure 400.

In some cases, supporting structures are coupled to corners and/or edges of packages structures to enhance the structural integrity of the package's edges and corners.

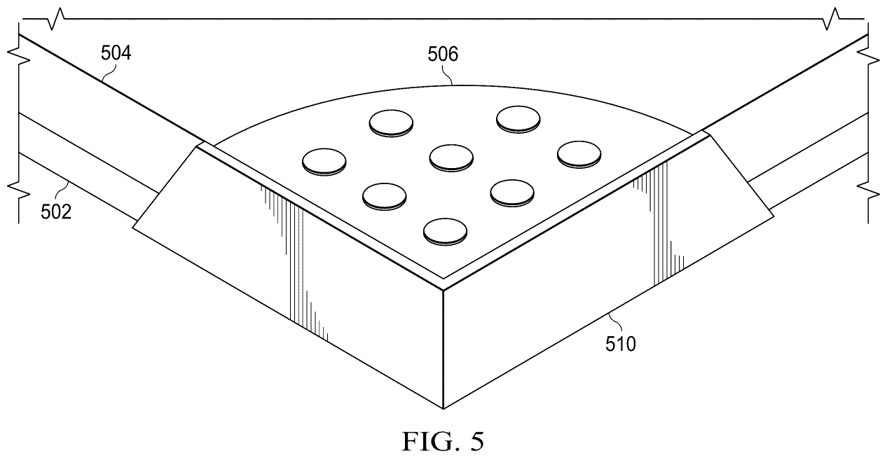

FIG. 5 illustrates an example of supporting structure 510, according to one or more implementations of the disclosure. As shown, supporting structure 510 is coupled to corner structure 506 adjoining encapsulation structure 504.

In some examples, support structure 510 can be a high strength supporting structure, such as clamps or braces, to strengthen the corners. Support structure 510 can have an L-shaped as shown in FIG. 5 or may have another shape. Supporting structure 510 is positioned in such a manner that it snugly fits the corner it is intended to reinforce. In the example shown in FIG. 5, one leg of the ‘L’ of the L-shaped support structure 510 extends along one edge of corner structure 510 and the other leg extends perpendicularly along the adjacent edge. In some examples, supporting structure 510 can be adhesively attached to the edges of corner structure 506 and substrate 502 below corner structure 506 to enhance structural integrity and resilience. In some examples, supporting structure 510 can extend from corner structure 506 and substrate below corner structure 506 to adjoining encapsulation structure 504 and substrate 502 below encapsulation structure 504. In some implementations, the arrangement of the supporting structure is used to ensure reinforcement without impeding the functionality or accessibility of corner structure 510's surfaces and the mounted components.

While the description herein exemplifies on L-shaped profiles for supporting structure 510, it is important to note that this is not a limitation of supporting structure 510. The concept encompasses the use of various shapes and configurations of supporting structures that can be adhesively attached or otherwise affixed to the corners, as dictated by specific design requirements, aesthetic considerations, or functional necessities of the semiconductor package.

In some examples, supporting structure 510 can be fabricated from stainless steel due to its durability and mechanical strength. In some examples, supporting structure 510 can include any suitable materials, including but not limited to aluminum, titanium, and reinforced polymers, depending on varying requirements of thermal conductivity, weight reduction, and cost-effectiveness. The high strength material of support structure 510 can enhance the structural integrity of the package's corners, serving as a safeguard against mechanical impacts that the package may encounter. This reinforcement can ensure the protection of the internal chip, mitigating the risk of damage from external forces and preserving the operational reliability of the encapsulated semiconductor device.

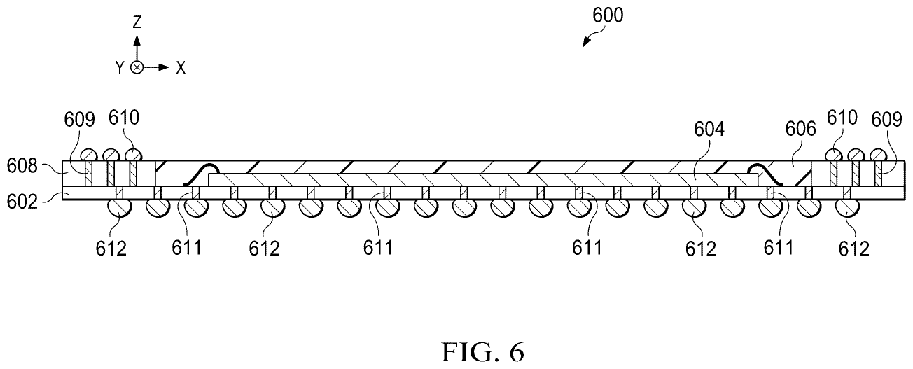

FIG. 6 illustrates an example side view of an example package structure 600, according to one or more implementations of the disclosure. As shown, package structure 600 includes substrate 602, chip 604 disposed on substrate 602, encapsulation structure 606 encapsulating chip 604, and corner structures 608 disposed on corner areas of substrate 602. In some implementations, package structure 600 is an example, at a side view, of package structure 300 in FIG. 3. For the sake of brevity, the description of the elements in FIG. 6 that are substantially the same or similar to those previously described in FIG. 3 will not be reiterated here. It is to be understood that these elements possess analogous structural and functional characteristics as those discussed with reference to FIG. 3.

In the shown example, corner structures 608 are disposed on corner areas of a surface of substrate 602, and encapsulation structure 606 does not extend to cover corner structures 608. In some implementations, substrate 602 includes a first material, and corner structures 608 include a second material. In some examples, the first material of substrate 602 is the same as the second material of corner structures 608. In some examples, the first material of substrate 602 is similar to the second material corner structures 608 in terms of at least one of electrical insulation resistivity or thermal expansion coefficient. For example, a difference in at least one of electrical insulation resistivity or thermal expansion coefficient between the first material and the second material is within a range or below a threshold, such as 0.5%-5% of the corresponding value of the first material or the second material.

By using the same or similar material as substrate 602 for the encapsulant material at the corners of package structure 600, the warping of package corners can be mitigated, potentially improving the deformation caused by the mismatch in thermal expansion between the encapsulation structure 606 and substrate 602.

In the shown example, corner structures 608 include contact structures 609 and solder bumps 610 that are coupled to contact structures 609 and that are disposed on an outward surface of corner structures 608 that is opposing a back surface of substrate 602. Solder bumps 610 serve as the means of electrical and mechanical connection between corner structures 608 and other components/systems. Corner structures 608, which include the same or substantially the same material as substrate 602, can be used to provide more solder bumps and contact structures to lead out internal interconnect pads, increasing the interconnect density of package structure 600. By utilizing the space provided by corner structures 608, more interconnect ports, such as solder bumps 610 and contact structures 609, can be brought out on the upper surface of package structure 600, which can serve as testing and maintenance interfaces (to avoid package damage caused by desoldering at the back side) or connect with other package interconnect ports, increasing the overall interconnect density of the package structure 600.

Corner structures 608 incorporating solder bumps 610 and contact structures 609 can serve various purposes, such as facilitating alignment during assembly, enabling enhanced interconnectivity with adjoining modules, or providing designated areas for additional functional elements like testing points or thermal management features.

In the shown example, solder bumps 612 are disposed on a back side of substrate 602. Solder bumps 612 serve as the means of electrical and mechanical connection between substrate 602 and other components/systems, such as a PCB. In some examples, solder bumps 612 have spherical or near-spherical formations that are arrayed on a surface of substrate 602, facilitating the establishment of interconnections. The dimensions of solder bumps 612 can be determined based on the specific requirements of package structure 600, with diameters ranging from a few micrometers to several hundred micrometers.

The arrangement of solder bumps 612 can follow a pre-defined pattern that aligns with corresponding contact structures 611 in substrate 602, improving the efficiency of electrical pathways and reducing signal latency. This pattern can be designed in a grid-like configuration, such as BGA, which allows for a high density of connections within a limited space, enhancing the overall performance and scalability of the semiconductor device.

The material composition of solder bumps 610 and 612 can include lead-based or lead-free alloys, with the specific alloy chosen based on considerations such as melting temperature, mechanical strength, and compatibility with the thermal expansion properties of substrate 602 and corner structures 608 to ensure reliable electrical connections and mechanical stability throughout the device's operational lifespan.

In some examples, contact structures 609 and 611 can include materials of high thermal conductivity to enhance the package's capability for heat dissipation. By leveraging the thermal conductive properties of these materials within the contact structures 609 and 611, the package can facilitate the removal of excess heat, thereby contributing to the improved thermal management and overall performance stability of the device.

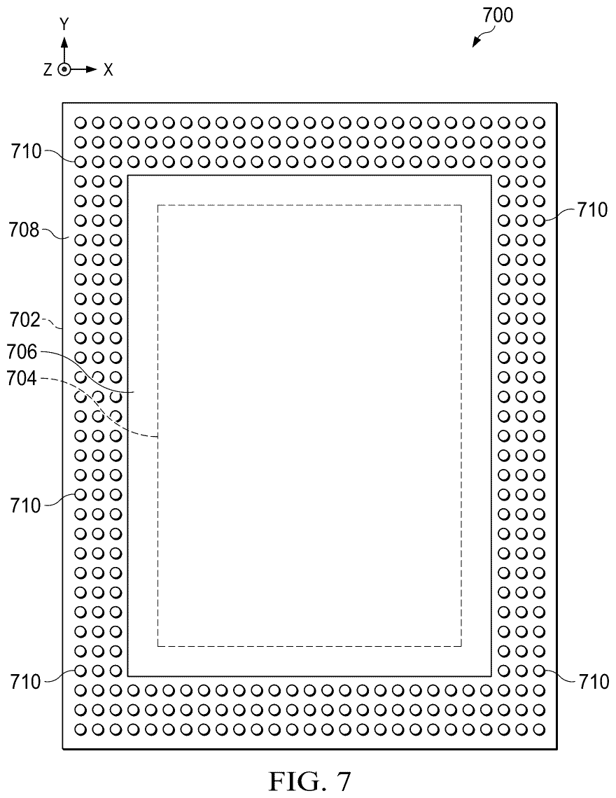

FIG. 7 illustrates an example top view of an example package structure 700, according to one or more implementations of the disclosure. As shown, package structure 700 includes substrate 702, chip 704 disposed on substrate 702, encapsulation structure 706 encapsulating chip 704, and peripheral structures 708 disposed on peripheral areas of substrate 702.

Substrate 702 can be composed of a rigid or flexible material that provides mechanical support for the mounted semiconductor devices, such as chip 704, and facilitates the electrical interconnection between these devices and external circuitry. Substrate 702 can include any suitable material including, but not limited to, ceramic, silicon, or organic materials like BT resin, FR4, and polyimide.

In some examples, substrate 702 incorporates multiple layers, including conductive traces and vias, which enable the routing of electrical signals, power, and ground connections throughout the package. Additionally, the substrate 702 can include specialized areas or pads for the attachment of semiconductor dies, as well as for the placement of external connection points such as solder balls or pins in BGA or PGA configurations, respectively.

Substrate 702 can also integrate passive components, such as resistors or capacitors, and employ materials with specific thermal, electrical, or mechanical properties to address particular performance requirements. For example, substrate 702 can use high thermal conductivity materials in areas prone to high heat generation, to aid in heat dissipation and maintain the reliability and longevity of the semiconductor devices.

Chip 704 is disposed on substrate 702. Chip 704 includes functional electronic circuitry composed of micro-scale electronic elements including, but not limited to, transistors, diodes, and passive components, which are interconnected to execute a diverse spectrum of electronic functions ranging from data processing to signal amplification.

Chip 704 can be any suitable type of chip, including but not limited to microprocessor chips, memory chips, microcontroller chips, DSP chips, FPGA chips, ASIC chips, or GPA chips.

Chip 704 can be fabricated from semiconductor materials, such as silicon (Si), gallium arsenide (GaAs), silicon carbide (SiC), gallium nitride (GaN), germanium (Ge), or silicon germanium (SiGe).

Chip 704 is encapsulated within encapsulation structure 706. Encapsulation structure 706 covers a surface of chip 704 and a portion of a surface area of substrate 702 that extends beyond chip 704. Encapsulation structure 706 provides chip 704 with protection against environmental hazards such as moisture, contaminants, and physical impacts. The material of encapsulation structure 706 can be selected to ensure compatibility with chip 704 and other package components, focusing on properties such as thermal stability, mechanical strength, and chemical resistance. In some examples, encapsulation structure 706 can be composed of any suitable material, including but not limited to epoxy resins, silicone, polyurethanes, acrylics, thermoplastics, or ceramics.

Note that in the shown example of FIG. 7, package structure 700 is shown to include one chip for illustrative purposes. In some examples, package structure 700 can have any suitable number of chips, such as 2, 5, or 10. In some implementations, the chips can be stacked on substrate 702. In some implementations, the chips can be stacked in any suitable manner, such as in an overlapping manner or in a staircase manner.

In the shown example, peripheral structures 708 are disposed on peripheral areas of substrate 702, and encapsulation structure 706 does not extend to cover peripheral structures 708. In some implementations, the peripheral areas include areas of a first surface (e.g., front surface) of substrate 702 that extend from edges of substrate 702 to a distance towards chip 704, such that encapsulation structure 706 covers a surface of chip 704 and a second area of the first surface of substrate 702 that extends beyond chip 704. In some examples, the second area includes a portion of the first surface of substrate 702 that extends beyond chip 704, excluding the peripheral areas of the first surface.

The peripheral areas where peripheral structures 708 are disposed include a portion of surface areas of substrate 702 that extend from edges of substrate 702 to a distance towards chip 704, such that encapsulation structure 706 covers chip 704 and a portion of surface areas of substrate 702 that extend beyond chip 704. In some implementations, substrate 702 includes a first material, and peripheral structures 708 include a second material. In some examples, the first material of substrate 702 is the same as the second material of peripheral structures 708. In some examples, the first material of substrate 702 is similar to the second material peripheral structures 708 in terms of at least one of electrical insulation resistivity or thermal expansion coefficient. For example, a difference in at least one of electrical insulation resistivity or thermal expansion coefficient between the first material and the second material is within a range or below a threshold, such as 0.5%-5% of the corresponding value of the first material or the second material.

By using the same or similar material as substrate 702 for the encapsulant material at the corners of package structure 700, the warping of package corners can be mitigated, potentially improving the deformation caused by the mismatch in thermal expansion between the encapsulation structure 706 and substrate 702.

Peripheral structures 708 are shaped and dimensioned with the exemplary implementations showcasing a “rectangular frame” or a “double-rectangular structure.” As shown, peripheral structures 708 features an outer rectangle that delineates the boundary of the structure, and an inner rectangle, set parallel to the outer rectangle's sides, creating a uniform border or frame around encapsulation structure 706. The space between the inner and outer rectangles forms a continuous, hollowed band or corridor, maintaining a width around the perimeter of the inner rectangle. However, peripheral structures 708 are not limited to these configurations alone. In some examples, peripheral structures 708 can have any suitable geometries, including but not limited to discontinuous or segmented rectangular frame.

The size and geometry of peripheral structures 708 can be determined based on several factors, including but not limited to the overall dimensions of substrate 702, the spatial requirements of the mounted components, and the intended application of the semiconductor package structure 700.

In some examples, peripheral structures 708 include contact structures (not shown) within peripheral structures 708 and solder bumps 710 that are coupled to the contact structures and that are disposed on an outward surface of peripheral structures 708 that is opposing a back surface of substrate 702. Solder bumps 710 serve as the means of electrical and mechanical connection between corner structures 308 and other components/systems. Peripheral structures 708, which include the same or substantially the same material as substrate 702, can be used to provide more solder bumps and contact structures to lead out internal interconnect pads, increasing the interconnect density of package structure 700. By utilizing the space provided by peripheral structures 708, more interconnect ports, such as solder bumps 710 and the contact structures coupled therewith, can be brought out on the upper surface of package structure 700, which can serve as testing and maintenance interfaces (to avoid package damage caused by desoldering at the back side) or connect with other package interconnect ports, increasing the overall interconnect density of the package structure 700.

In some examples, solder bumps 710 have spherical or near-spherical formations that are arrayed on a surface of peripheral structures 708, facilitating the establishment of interconnections. The dimensions of solder bumps 710 can be determined based on the specific requirements of peripheral structures 708, with diameters ranging from a few micrometers to several hundred micrometers.

The arrangement of solder bumps 710 can follow a pre-defined pattern that aligns with corresponding contact structures in peripheral structures 708, improving the efficiency of electrical pathways and reducing signal latency. This pattern can be designed in a grid-like configuration, such as BGA, which allows for a high density of connections within a limited space, enhancing the overall performance and scalability of the semiconductor device.

The material composition of solder bumps 710 can include lead-based or lead-free alloys, with the specific alloy chosen based on considerations such as melting temperature, mechanical strength, and compatibility with the thermal expansion properties of peripheral structures 708 to ensure reliable electrical connections and mechanical stability throughout the device's operational lifespan.

Peripheral structures 708 incorporating solder bumps 710 and contact structures therewith can serve various purposes, such as facilitating alignment during assembly, enabling enhanced interconnectivity with adjoining modules, or providing designated areas for additional functional elements like testing points or thermal management features.

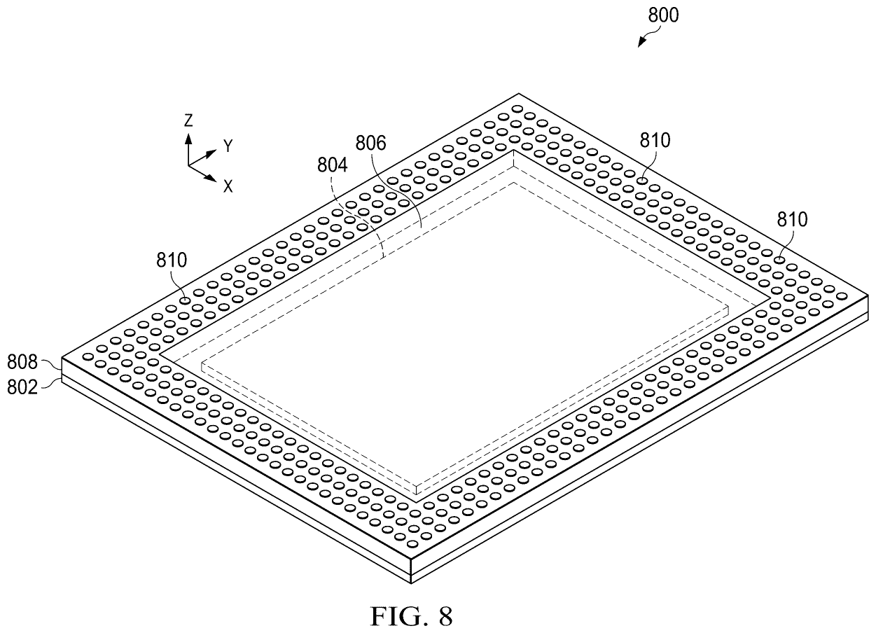

FIG. 8 illustrates an example perspective view of an example package structure 800, according to one or more implementations of the disclosure. As shown, package structure 800 includes substrate 802, chip 804 disposed on substrate 802, encapsulation structure 806 encapsulating chip 804, and peripheral structures 808 disposed on peripheral areas of substrate 802. In some implementations, package structure 800 is an example, at a perspective view, of package structure 700 in FIG. 7. For the sake of brevity, the description of the elements in FIG. 8 that are substantially the same or similar to those previously described in FIG. 7 will not be reiterated here. It is to be understood that these elements possess analogous structural and functional characteristics as those discussed with reference to FIG. 7.

Substrate 802 can be composed of a rigid or flexible material that provides mechanical support for the mounted semiconductor devices, such as chip 804, and facilitates the electrical interconnection between these devices and external circuitry. Substrate 802 can include any suitable material, including but not limited to ceramic, silicon, or organic materials like BT resin, FR4, and polyimide.

Chip 804 is disposed on substrate 802. Chip 804 includes functional electronic circuitry composed of micro-scale electronic elements, including but not limited to transistors, diodes, and passive components, which are interconnected to execute a diverse spectrum of electronic functions ranging from data processing to signal amplification.

Chip 804 is encapsulated within encapsulation structure 806. Encapsulation structure 806 covers a surface of chip 804 and a portion of a surface area of substrate 802 that extends beyond chip 804. The material of encapsulation structure 806 can be selected to ensure compatibility with chip 804 and other package components. In some examples, encapsulation structure 806 can be composed of any suitable material, including but not limited to epoxy resins, silicone, polyurethanes, acrylics, thermoplastics, or ceramics.

In the shown example, peripheral structures 808 are disposed on peripheral areas of substrate 802, and encapsulation structure 806 does not extend to cover peripheral structures 808. In some implementations, substrate 802 includes a first material, and peripheral structures 808 include a second material. In some examples, the first material of substrate 802 is the same as the second material of peripheral structures 808. In some examples, the first material of substrate 802 is similar to the second material peripheral structures 808 in term of at least one of electrical insulation resistivity or thermal expansion coefficient. For example, a difference in at least one of electrical insulation resistivity or thermal expansion coefficient between the first material and the second material is within a range or below a threshold, such as 0.5%-5% of the corresponding value of the first material or the second material.

Peripheral structures 808 are shaped and dimensioned with the exemplary implementations showcasing a “rectangular frame” or a “double-rectangular structure.” As shown, peripheral structures 708 features an outer rectangle that delineates the boundary of the structure, and an inner rectangle, set parallel to the outer rectangle's sides, creating a uniform border or frame around encapsulation structure 806. The space between the inner and outer rectangles forms a continuous, hollowed band or corridor, maintaining a width around the perimeter of the inner rectangle. However, peripheral structures 808 are not limited to these configurations alone. In some examples, peripheral structures 808 can have any suitable geometries, including but not limited to discontinuous or segmented rectangular frame.

In some examples, peripheral structures 808 include contact structures (not shown) within peripheral structures 808 and solder bumps 810 that are coupled to the contact structures and that are disposed on an outward surface of peripheral structures 808 that is opposing a back surface of substrate 802.

Peripheral structures 808, which include the same or substantially the same material as substrate 802, can be used to provide more solder bumps and contact structures to lead out internal interconnect pads, increasing the interconnect density of package structure 800. By utilizing the space provided by peripheral structures 808, more interconnect ports, such as solder bumps 810 and the contact structures coupled therewith, can be brought out on the upper surface of package structure 800, which can serve as testing and maintenance interfaces (to avoid package damage caused by desoldering at the back side) or connect with other package interconnect ports, increasing the overall interconnect density of the package structure 800.

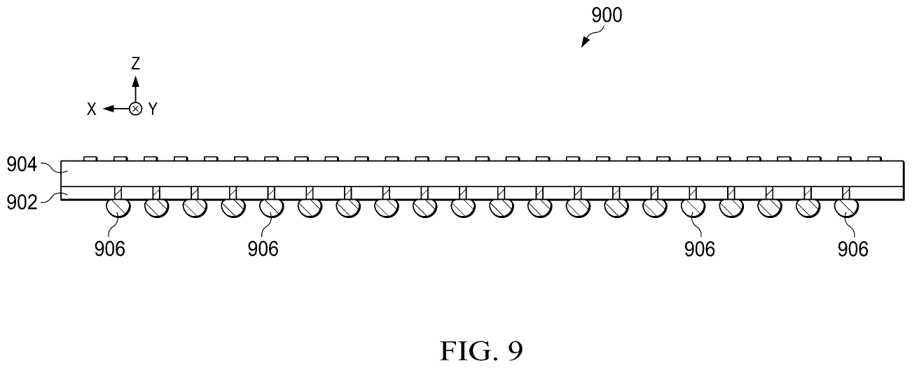

FIG. 9 illustrates an example side view of an example package structure 900, according to one or more implementations of the disclosure. As shown, package structure 900 includes substrate 902, peripheral structures 904 disposed on substrate 902, and solder bumps 906 disposed on a back surface of substrate 902. In some implementations, package structure 900 is an example, at a side view, of package structure 700 in FIG. 7. For the sake of brevity, the description of the elements in FIG. 9 that are substantially the same or similar to those previously described in FIG. 7 will not be reiterated here. It is to be understood that these elements possess analogous structural and functional characteristics as those discussed with reference to FIG. 7.

In the shown example, peripheral structures 904 are disposed on peripheral areas of substrate 902. In some implementations, substrate 902 includes a first material, and peripheral structures 908 include a second material. In some examples, the first material of substrate 902 is the same as the second material of peripheral structures 908. In some examples, the first material of substrate 902 is similar to the second material peripheral structures 908 in term of at least one of electrical insulation resistivity or thermal expansion coefficient. For example, a difference in at least one of electrical insulation resistivity or thermal expansion coefficient between the first material and the second material is within a range or below a threshold, such as 0.5%-5% of the corresponding value of the first material or the second material.

In the shown example, solder bumps 906 are disposed on a back side of substrate 902. Solder bumps 906 serve as the means of electrical and mechanical connection between substrate 902 and other components/systems, such as a PCB. In some examples, solder bumps 906 have spherical or near-spherical formations that are arrayed on a surface of substrate 902, facilitating the establishment of interconnections. The dimensions of solder bumps 906 can be determined based on the specific requirements of package structure 600, with diameters ranging from a few micrometers to several hundred micrometers.

The arrangement of solder bumps 906 can follow a pre-defined pattern that aligns with corresponding contact structures (not shown) in substrate 902, improving the efficiency of electrical pathways and reducing signal latency. This pattern can be designed in a grid-like configuration, such as BGA, which allows for a high density of connections within a limited space, enhancing the overall performance and scalability of the semiconductor device.

The material composition of solder bumps 906 can include lead-based or lead-free alloys, with the specific alloy chosen based on considerations such as melting temperature, mechanical strength, and compatibility with the thermal expansion properties of substrate 902 to ensure reliable electrical connections and mechanical stability throughout the device's operational lifespan.

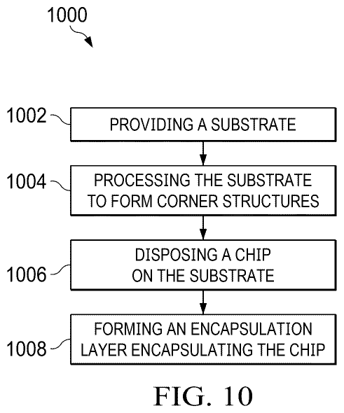

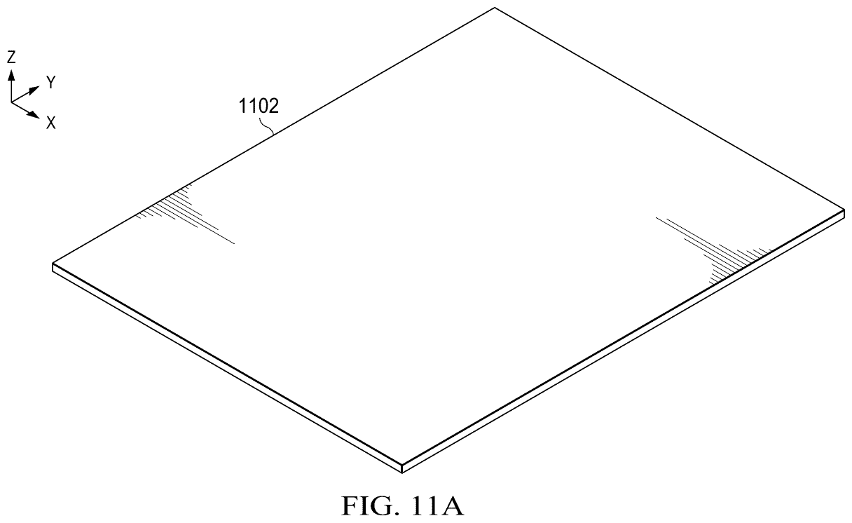

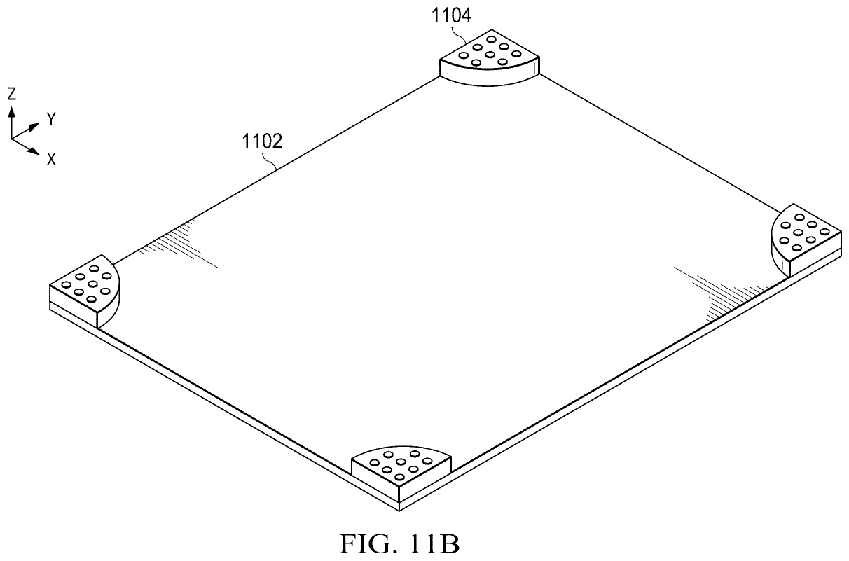

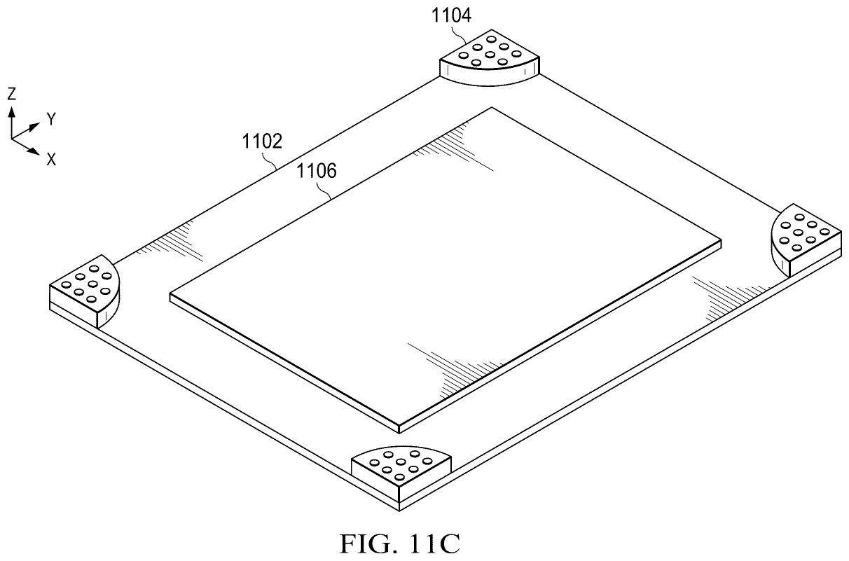

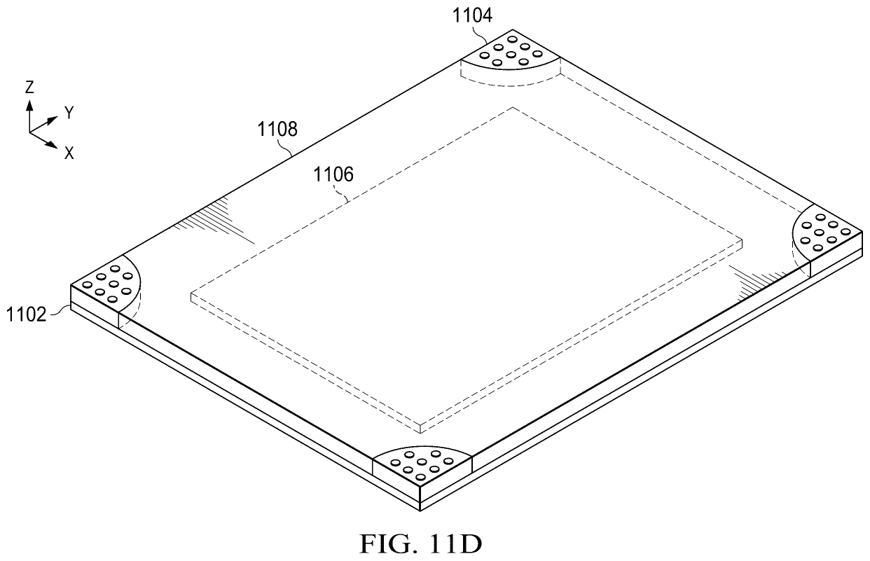

FIG. 10 illustrates a block diagram of an example process 1000 of manufacturing a package structure, according to one or more implementations of the disclosure. Process 1000 will be described with reference to the structures as illustrated in FIGS. 11A-11D. It should be noted that while the structures in FIGS. 11A-11D are described herein as examples, these are not meant to be limiting, process 1000 can be performed with respect to any suitable structures, such as package structures 300, 400, 500, 600, 700, 800, or 900. The operations shown in process 1000 may not be exhaustive and that other operations can be performed as well before, after, or in between any of the illustrated operations. Further, some of the operations may be performed simultaneously, or in a different order than shown in FIG. 10.

A substrate is provided (1002). For example, referring to FIG. 11A, substrate 1102 is provided. In some examples, an appropriate base material can be selected for substrate 1102, which may range from traditional FR4 for printed circuit boards to ceramics or silicon for high-performance applications. The chosen material undergoes precision cutting to define the substrate's dimensions, followed by surface preparation techniques such as cleaning and etching to ensure adhesion for subsequent layers. Photolithographic processes are then employed to delineate circuit patterns on the substrate, involving the application of a photosensitive resist, exposure to a patterned light source, and chemical development to reveal the desired circuitry layout. Conductive materials are deposited onto the patterned areas through methods such as electroplating or sputtering, forming the intricate network of traces and pads essential for electrical connectivity. The substrate can also undergo drilling or laser ablation to create vias, facilitating interlayer connections.

The substrate is processed to form corner structures (1004). For example, referring to FIG. 11B, corner structures 1104 are formed on substrate 1102. As shown, each corner structure 1104, designed with a pie-shaped configuration, is disposed on a corner area of substrate 1102. Although corner structures 1104 are shaped and dimensioned with the exemplary implementations showcasing pie-shaped configurations, corner structures 1104 are not limited to these configurations alone. In some examples, corner structures 1104 can have any suitable geometries, including but not limited to square, rectangular, regular, or irregular shapes.

The size and geometry of each one of corner structure 1104 can be determined based on several factors, including but not limited to the overall dimensions of substrate 1102, the spatial requirements of the mounted components, and the intended application of the semiconductor package.

Corner structures 1104 can be formed using methods such as lamination or cutting techniques based on the desired outcome and manufacturing considerations. In an example lamination approach, pre-shaped corner structures 1104 are aligned and affixed to the corner areas of substrate 1102, employing heat and pressure to bond the structures seamlessly. This method can be used for adding additional layers or features to the existing substrate without altering its base structure. Conversely, the cutting technique involves the removal of material from substrate 1102 itself to form the pie-shaped corner structures 1104 directly within the substrate 1102's framework. This method can be used for creating integrated corner features without the need for additional materials, thereby maintaining the substrate's homogeneity.

A chip is disposed on the substrate (1006). For example, referring to FIG. 11C, chip 1106 is disposed on substrate 1102. Initially, substrate 1102 can be prepared with a designated area for chip placement, which may include pre-patterned conductive traces, pads, and, if necessary, adhesive or solder layers to facilitate bonding. Chip 1106, including an array of electronic circuits on its surface, is then aligned with substrate 1102 using high-precision placement equipment to ensure accurate positioning over the designated area. Following alignment, chip 1106 is securely attached to substrate 1102 using one of several bonding techniques, which may include reflow soldering, thermocompression bonding, or the use of conductive adhesives, depending on the requirements of the application and the materials involved. Finally, the assembly may undergo additional processes such as underfilling, where a specially formulated compound is dispensed between chip 1106 and substrate 1102 to fill any voids, providing additional mechanical support and enhancing thermal conductivity.

An encapsulation structure is formed to encapsulate the chip (1008). Referring to FIG. 11D, encapsulation structure 1108 is formed to encapsulate chip 1106. Following the securement of chip 1106, encapsulation structure 1108 can be formed using a selective deposition technique, where the encapsulant material, such as an epoxy molding compound, is applied over chip 1106 and the immediate surrounding area on substrate 1102. This technique involves controlling the encapsulant's flow or employing a mold that defines the encapsulation boundary, ensuring that the encapsulant envelops chip 1106 and bonds to substrate 1102 without extending over corner structures 1104.

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described example implementations, but should be defined only in accordance with the following claims and their equivalents. Accordingly, other implementations also are within the scope of the claims.

What is claimed is:

1. A package structure, comprising:
a substrate comprising a first material;
a chip disposed on a first surface of the substrate;
corner structures disposed on corner areas of the first surface, wherein the corner structures comprise a second material; and
an encapsulation structure encapsulating the chip, wherein the encapsulation structure covers a surface of the chip and a first area of the first surface of the substrate that extends beyond the chip.

2. The package structure according to claim 1, wherein the substrate comprises first contact structures and first solder bumps coupled to the first contact structures, wherein the first solder bumps are placed on a second surface of the substrate opposing the first surface of the substrate, and
at least one of the corner structures comprises second contact structures and second solder bumps coupled to the second contact structures, wherein the second solder bumps are placed on an outward surface of the at least one of the corner structures that is opposing the second surface of the substrate.

3. The package structure according to claim 2, wherein the second contact structures comprise a material having a thermal expansion coefficient exceeding a threshold.

4. The package structure according to claim 1, further comprising a supporting structure, wherein the supporting structure is coupled to one of the corner structures.

5. The package structure according to claim 4, wherein the supporting structure is coupled to the one of the corner structures using adhesive bonding.

6. The package structure according to claim 4, wherein the supporting structure comprises a material of stainless steel.

7. The package structure according to claim 4, wherein the supporting structure is an L-shape structure.

8. The package structure according to claim 1, wherein the corner structures occupy at least 10% of a total area of the first surface that extends beyond the chip.

9. The package structure according to claim 1, wherein the encapsulation structure comprises an epoxy molding compound.

10. The package structure according to claim 1, wherein the package structure comprises peripheral structures disposed on peripheral areas of the first surface of the substrate, the peripheral areas comprise areas of the first surface that extend from edges of the substrate to a distance towards the chip, wherein the encapsulation structure covers a surface of the chip and a second area of the first surface of the substrate that extends beyond the chip, and wherein the peripheral areas comprise the corner areas.

11. The package structure according to claim 1, wherein:
the first material is the same as the second material; or
the first material is similar to the second material in that a difference in at least one of electrical insulation resistivity or thermal expansion coefficient between the first material and the second material is below a threshold.

12. A package structure, comprising:
a substrate;
a chip disposed on a first surface of the substrate, wherein the substrate comprises first contact structures and first solder bumps coupled to the first contact structures, and the first solder bumps are placed on a second surface of the substrate opposing the first surface of the substrate;
corner structures disposed on corner areas of the first surface, wherein at least one of the corner structures comprises second contact structures and second solder bumps coupled to the second contact structures, and the second solder bumps are placed on an outward surface of the at least one of the corner structures that is opposing the second surface of the substrate; and
an encapsulation structure encapsulating the chip, wherein the encapsulation structure covers a surface of the chip and a first area of the first surface of the substrate that extends beyond the chip.

13. The package structure according to claim 12, wherein the substrate comprises a first material, and the corner structures comprise a second material, and wherein:
the first material is the same as the second material; or
the first material is different from the second material, and a difference in at least one of electrical insulation resistivity or thermal expansion coefficient between the first material and the second material is within a range.

14. The package structure according to claim 13, further comprising a supporting structure, wherein the supporting structure is coupled to one of the corner structures.

15. The package structure according to claim 14, wherein the supporting structure is coupled to the one of the corner structures using adhesive bonding.

16. The package structure according to claim 14, wherein the supporting structure comprises a material of stainless steel.

17. The package structure according to claim 12, wherein the corner structures occupy at least 10% of a total area of the first surface that extends beyond the chip.

18. The package structure according to claim 12, wherein the encapsulation structure comprises an epoxy molding compound.

19. A package structure, comprising:
a substrate comprising a first material;
chips stacked on a first surface of the substrate;
corner structures disposed on corner areas of the first surface of the substrate, wherein the corner structures comprise a second material, and wherein:
the first material is the same as the second material; or
the first material is different from the second material, and a difference in at least one of electrical insulation resistivity or thermal expansion coefficient between the first material and the second material is within a range; and
an encapsulation structure encapsulating the chips, wherein the encapsulation structure covers a surface of at least one of the chips and a first area of the first surface of the substrate.

20. The package structure according to claim 19, wherein the chips are stacked in a form of staircase.
